(19) United States
(12) Patent Application Publication
(10) Pub. No.: US 2025/0204266 A1
(43) Pub. Date: Jun. 19, 2025

(54) SEMICONDUCTOR DEVICE AND MANUFACTURING METHOD THEREOF

(71) Applicant: UNITED MICROELECTRONICS CORP., Hsin-Chu City (TW)

(72) Inventors: Da-Jun Lin, Kaohsiung City (TW); Chung-Yi Chiu, Tainan City (TW); Bin-Siang Tsai, Changhua County (TW); Fu-Yu Tsai, Tainan City (TW)

(73) Assignee: UNITED MICROELECTRONICS CORP., Hsin-Chu City (TW)

(21) Appl. No.: 18/413,063

(22) Filed: Jan. 16, 2024

(30) Foreign Application Priority Data
Dec. 15, 2023 (TW) 112149062

(51) Int. Cl. H10N 50/80; G11C 11/16; H10N 50/01; H10N 50/10

(52) U.S. Cl. CPC H10N 50/80; G11C 11/161; G11C 11/1675; H10N 50/01; H10N 50/10

(57) ABSTRACT

A semiconductor device includes a substrate, magnetic tunnel junction (MTJ) structures, and a write structure. The MTJ structures are disposed above the substrate. The write structure is disposed on and connected with the MTJ structures. The write structure includes spin-orbit torque (SOT) patterns and an electrically conductive layer. The SOT patterns are separated from one another, and each of the SOT patterns is disposed on and connected with one of the MTJ structures. The conductive layer covers the SOT patterns. The electrically conductive layer is partly disposed above the SOT patterns in a vertical direction and partly disposed between the SOT patterns in a first horizontal direction.

### BACKGROUND OF THE INVENTION

### 1. Field of the Invention

The present invention relates to a semiconductor device and a manufacturing method thereof, and more particularly, to a semiconductor device including a magnetic tunnel junction (MTJ) structure and a manufacturing method thereof.

### 2. Description of the Prior Art

There are essentially two types of data memory devices used in electronic products, non-volatile and volatile memory devices. Magnetic random access memory (MRAM) is a kind of non-volatile memory technology. Unlike current industry-standard memory devices, MRAM uses magnetism instead of electrical charges to store data. In general, MRAM cells include a data layer and a reference layer. The data layer is composed of a magnetic material and the magnetization of the data layer can be switched between two opposing states by an applied magnetic field for storing binary information. The reference layer can be composed of a magnetic material in which the magnetization is pinned so that the strength of the magnetic field applied to the data layer and partially penetrating the reference layer is insufficient for switching the magnetization in the reference layer. During the read operation, the resistance of the MRAM cell is different when the magnetization alignments of the data layer and the reference layer are the same or not, and the magnetization polarity of the data layer can be identified accordingly. The structure of MRAM devices will vary depending on the technology used to magnetize the data layer. Currently, spin-transfer torque (STT) MRAM and spin-orbit torque (SOT) MRAM are relatively common technology. The STT MRAM and the SOT MRAM have different advantages and disadvantages respectively. How to improve the shortcomings of MRAM devices through structures, materials, and/or process design for enhancing the merchandize value is an ongoing research direction for people in related fields.

### SUMMARY OF THE INVENTION

A semiconductor device and a manufacturing method thereof are provided in the present invention. Spin-orbit torque (SOT) patterns and an electrically conductive layer are disposed in a write structure for reducing the overall electrical resistance of the write structure while maintaining the required programming performance and magnetization performance. The operation performance of the semiconductor device may be improved accordingly.

According to an embodiment of the present invention, a semiconductor device is provided. The semiconductor device includes a substrate, magnetic tunnel junction (MTJ) structures, and a write structure. The magnetic tunnel junction structures are disposed above the substrate. The write structure is disposed on and connected with the magnetic tunnel junction structures. The write structure includes spin-orbit torque (SOT) patterns and an electrically conductive layer. The spin-orbit torque patterns are separated from one another, and each of the spin-orbit torque patterns is disposed on and connected with one of the magnetic tunnel junction structures. The electrically conductive layer covers the spin-orbit torque patterns, and the electrically conductive layer is partly disposed above the spin-orbit torque patterns in a vertical direction and partly disposed between the spin-orbit torque patterns in a first horizontal direction.

According to another embodiment of the present invention, a manufacturing method of a semiconductor device is provided. The manufacturing method includes the following steps. Magnetic tunnel junction (MTJ) structures are formed above a substrate. A write structure is formed on the magnetic tunnel junction structures, the write structure is connected with the magnetic tunnel junction structures, and the write structure includes spin-orbit torque (SOT) patterns and an electrically conductive layer. The spin-orbit torque patterns are separated from one another, and each of the spin-orbit torque patterns is disposed on and connected with one of the magnetic tunnel junction structures. The electrically conductive layer covers the spin-orbit torque patterns, and the electrically conductive layer is partly disposed above the spin-orbit torque patterns in a vertical direction and partly disposed between the spin-orbit torque patterns in a first horizontal direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a semiconductor device according to an embodiment of the present invention.

FIG. 2 is a cross-sectional schematic drawing illustrating a semiconductor device according to an embodiment of the present invention.

FIG. 3 is a top-view schematic drawing illustrating a semiconductor device according to an embodiment of the present invention.

FIGS. 4-10 are schematic drawings illustrating a manufacturing method of a semiconductor device according to an embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, and FIG. 10 is a schematic drawing in a step subsequent to FIG. 9.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

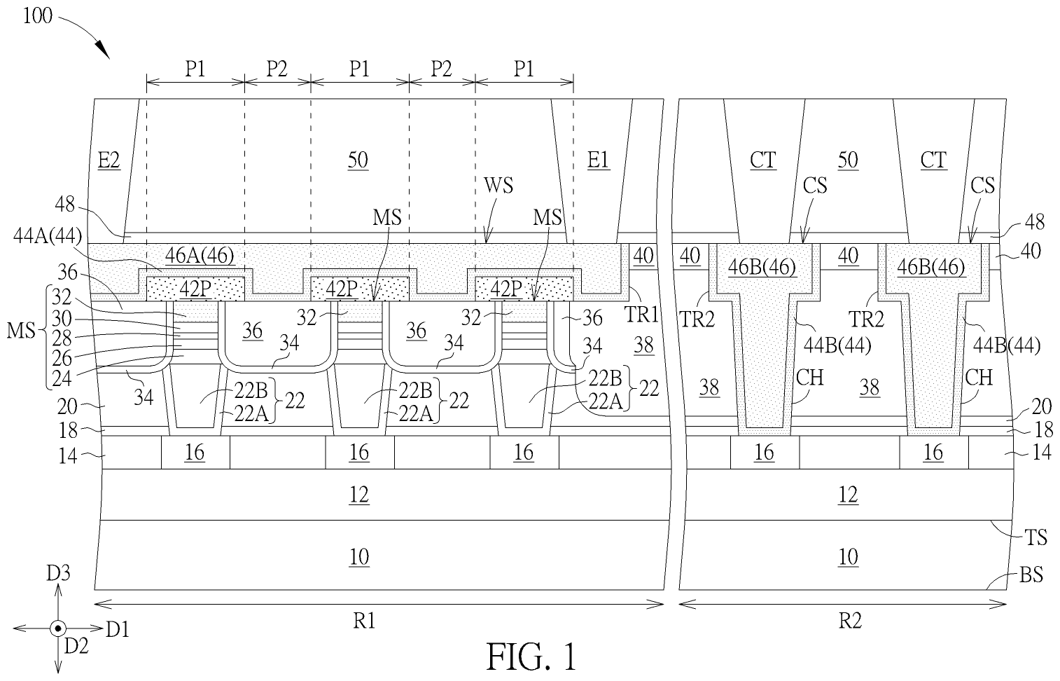

Please refer to FIG. 1. FIG. 1 is a schematic drawing illustrating a semiconductor device 100 according to an embodiment of the present invention. As shown in FIG. 1, the semiconductor device 100 includes a substrate 10, magnetic tunnel junction (MTJ) structures (such as MTJ structures MS), and a write structure WS. The MTJ structures MS are disposed above the substrate 10. The write structure WS is disposed on and connected with the MTJ structures MS. The write structure WS includes spin-orbit torque (SOT) patterns (such as SOT patterns 42P) and an electrically conductive layer 46A. The SOT patterns 42P are separated from one another, and each of the SOT patterns 42P is disposed on and connected with one of the MTJ structures MS. The electrically conductive layer 46A covers the SOT patterns 42P, and the electrically conductive layer 46A is partly disposed above the SOT patterns 42P in a vertical direction D3 and partly disposed between the SOT patterns 42P in a first horizontal direction D1. The SOT pattern 42P may be used to generate spin-orbit torque magnetization effect to the magnetic material in the MTJ structure MS for realizing programming operation of the memory device. However, the electrical resistivity of the material for forming the SOT pattern 42P is relatively high and is not conducive to related operations. When the SOT patterns 42P and the electrically conductive layer 46A are disposed in the write structure WS, the electrically conductive layer 46A with relatively low electrical resistivity may be used to reduce the overall electrical resistance of the write structure WS, the operation performance of the memory cell and the semiconductor device 100 may be enhanced and/or the power consumption for operating the semiconductor device 100 may be improved accordingly.

In some embodiments, the vertical direction D3 may be regarded as a thickness direction of the substrate 10. The substrate 10 may have a top surface TS and a bottom surface BS opposite to the top surface TS in the vertical direction D3, and the MTJ structures MS and the write structure WS may be disposed at the side of the top surface TS. A horizontal direction substantially orthogonal to the vertical direction D3 (such as the first horizontal direction D1, the second horizontal direction D2, and other horizontal directions) may be substantially parallel with the top surface TS and/or the bottom surface BS of the substrate 10, but not limited thereto. In this description, a distance between the bottom surface BS of the substrate 10 and a relatively higher location and/or a relatively higher part in the vertical direction D3 may be greater than a distance between the bottom surface BS of the substrate 10 and a relatively lower location and/or a relatively lower part in the vertical direction D3. The bottom or a lower portion of each component may be closer to the bottom surface BS of the substrate 10 in the vertical direction D3 than the top or upper portion of this component. Another component disposed above a specific component may be regarded as being relatively far from the bottom surface BS of the substrate 10 in the vertical direction D3, and another component disposed under a specific component may be regarded as being relatively close to the bottom surface BS of the substrate 10 in the vertical direction D3. It is worth noting that, in this description, a top surface of a specific component may include the topmost surface of this component in the vertical direction D3, and a bottom surface of a specific component may include the bottommost surface of this component in the vertical direction D3, but not limited thereto. In this description, the condition that a certain component is disposed between two other components in a specific direction may include a condition that the certain component is sandwiched between the two other components in the specific direction.

In some embodiments, the substrate 10 may include a first region R1 and a second region R2 and the MTJ structures MS and the write structure WS described above may be disposed above the first region R1. The first region R1 may be regarded as a memory cell region, and the second region R2 may be regarded as a logic region, but not limited thereto. In some embodiments, the semiconductor device 100 may further include a dielectric layer 12, a dielectric layer 14, connection structures 16, a stop layer 18, a dielectric layer 20, connection structures 22, a capping layer 34, a dielectric layer 36, a dielectric layer 38, a dielectric layer 40, and an interconnection structure CS. The dielectric layer 12, the dielectric layer 14, the connection structures 16, the stop layer 18, the dielectric layer 20, the dielectric layer 38, and the dielectric layer 40 may be partly disposed above the first region R1 and partly disposed above the second region R2. The capping layer 34 and the dielectric layer 36 may be disposed above the first region R1, and the interconnection CS may be disposed above the second region R2. In some embodiments, the substrate 10 may include a semiconductor substrate or a non-semiconductor substrate. The semiconductor substrate may include a silicon substrate, a silicon germanium semiconductor substrate or a silicon-on-insulator (SOI) substrate, and the non-semiconductor substrate may include a glass substrate, a plastic substrate, or a ceramic substrate, but not limited thereto. For example, when the substrate 10 includes a semiconductor substrate, a plurality of silicon-based field effect transistors (not shown), a dielectric layer covering the silicon-based field effect transistors (such as the dielectric layer 12 and the dielectric layer 14), and the connection structures 16 may be disposed on the semiconductor substrate, but not limited thereto. The stop layer 18 may be disposed between the dielectric layer 14 and the dielectric layer 20 in the vertical direction D3, and the connection structure 22 may be disposed under the corresponding MTJ structure MS. The connection structure 22 may penetrate through the dielectric layer 20 and the stop layer 18 in the vertical direction D3 and may be connected with the corresponding MTJ structure MS and the corresponding connection structure 16. The capping layer 34 may be disposed on the dielectric layer 20 and disposed on the sidewall of each of the MTJ structures MS, the dielectric layer 36 may be disposed on the capping layer 34, and the capping layer 34 and the dielectric layer 36 may be disposed between the MTJ structures MS located adjacent to each other in the horizontal direction. The dielectric layer 38 may be disposed on the dielectric layer 20 and the dielectric layer 36, and the dielectric layer 40 may be disposed on the dielectric layer 38.

In some embodiments, each of the MTJ structures MS may be electrically connected downward to the silicon-based field effect transistor described above via the connection structure 22 and the connection structure 16, and the interconnection structure CS may be electrically connected downward to the silicon-based field effect transistor via the connection structure 16, but not limited thereto. In some embodiments, each of the connection structures 16 may be regarded as a trench conductor mainly extending in the horizontal direction, the connection structure 22 may be regarded as a via conductor mainly extending in the vertical direction D3, and the interconnection structure CS may include a via conductor portion (such as a portion disposed in a contact hole CH) and a trench conductor portion disposed on the via conductor portion (such as a portion disposed in a second trench TR2). In some embodiments, the semiconductor device 100 may further include a stop layer 48, a dielectric layer 50, a first electrode E1, a second electrode E2, and connection structures CT. The stop layer 48 may be disposed above the first region R1 and the second region R2 and cover the dielectric layer 40, the write structure WS, and the interconnection structure CS. The dielectric layer 50 may be disposed on the stop layer 48, and the connection structure CT may penetrate through the dielectric layer 50 and the stop layer 48 in the vertical direction D3 for being connected with the corresponding interconnection structure CS. In some embodiments, the write structure WS may extend in the first horizontal direction D1, the first electrode E1 and the second electrode E2 are disposed on the write structure WS and may penetrate through the dielectric layer 50 and the stop layer 48 in the vertical direction D3 for being connected with the write structure WS, and the first electrode E1 and the second electrode E2 may be disposed above two opposite ends of the write structure WS in the first horizontal direction D1, respectively. Each of the MTJ structures MS, the corresponding write structure WS, and the corresponding connection structure 22 may constitute a memory cell, such as a magnetic random access memory (MRAM) cell. Electrical current may be formed in the write structure WS via the first electrode E1 and the second electrode E2, and the magnetic moment and the magnetization effect influencing the MTJ structure MS may be formed by the electrical current passing through the SOT patterns 42P in the write structure WS. In some embodiments, the magnetization effect generated by the electrical current passing through the write structure WS may be combined with the magnetization effect generated by the electrical current provided to the MTJ structure MS via the connection structure 22 to program the magnetic layer in the specific MTJ structure MS concurrently, but not limited thereto.

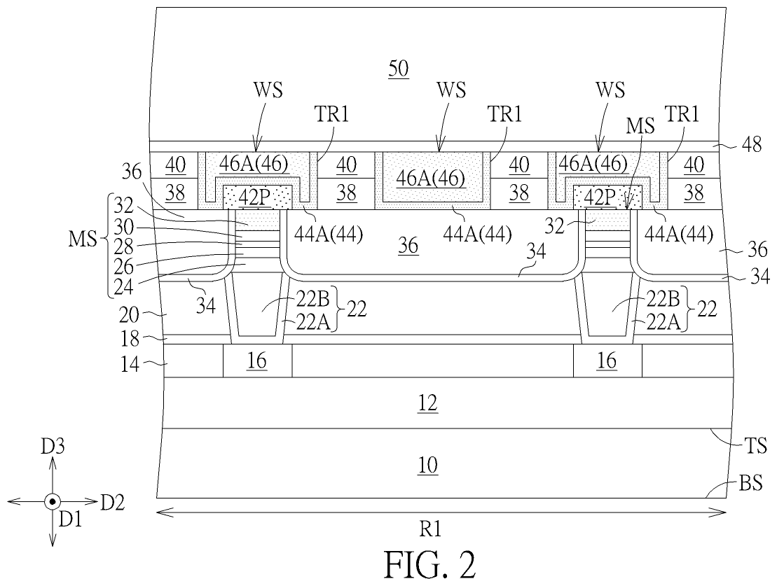

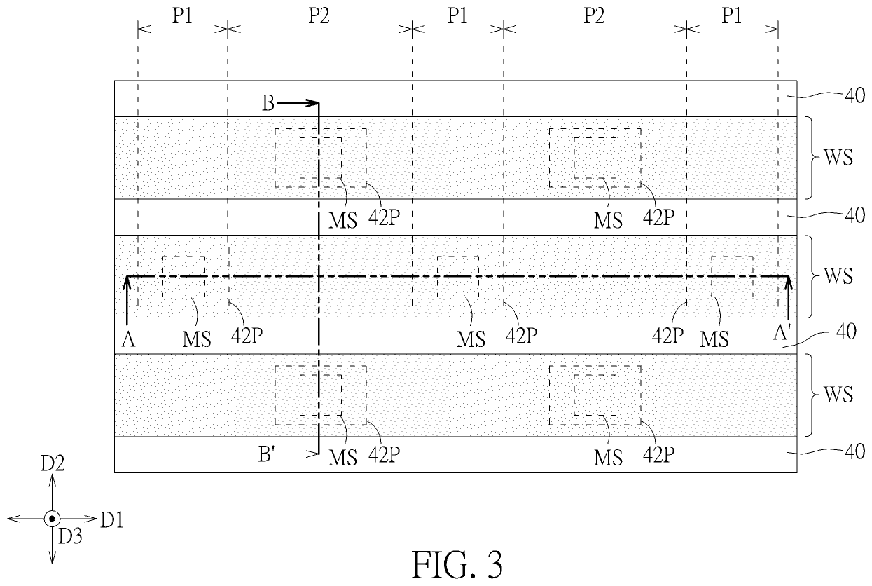

Please refer to FIGS. 1-3. FIG. 2 is a cross-sectional schematic drawing illustrating the semiconductor device in this embodiment, and FIG. 3 is a top-view schematic drawing illustrating the semiconductor device in this embodiment. In some embodiments, a part of FIG. 1 (such has a portion corresponding to the first region R1) may be regarded as a cross-sectional diagram taken along a line A-A′ in FIG. 3, and FIG. 2 may be regarded as a cross-sectional diagram taken along a line B-B′ in FIG. 3, but not limited thereto. In addition, FIG. 3 is a drawing mainly illustrating the allocation of the write structure WS, the SOT patterns 42P, the MTJ structures MS, and the dielectric layer 40 in the top-view diagram without illustrating other parts of the semiconductor device. As shown in FIGS. 1-3, in some embodiments, the semiconductor device 100 may include a plurality of write structures WS, each of the write structures WS may extend in the first horizontal direction D1, and the MTJ structures MS located corresponding to the same write structure WS may be arranged in the first horizontal direction D1. In addition, the write structures WS may be arranged in the second horizontal direction D2, and the MTJ structures MS located corresponding to different write structures WS adjacent to each other may be arranged and misaligned to each other in the second horizontal direction D2 for reducing the interference between the MTJ structures MS and reducing the area of the memory cell and/or enhancing the distribution density of the MTJ structures MS. In some embodiments, the write structure WS may be disposed in a dielectric layer (such as a dielectric layer composed of the dielectric layer 38 and the dielectric layer 40), the dielectric layer may include a first layer (such as the dielectric layer 38) and a second layer (such as the dielectric layer 40) disposed on the first layer, the write structure WS may be partly disposed in the dielectric layer 38 and partly disposed in the dielectric layer 40, and a dielectric constant of the dielectric layer 40 may be lower than a dielectric constant of the dielectric layer 38 for improving the isolation performance between the write structures WS adjacent to one another, but not limited thereto.

In some embodiments, each of the write structures WS may be disposed in a first trench TR1 located in the dielectric layer 38 and the dielectric layer 40, and the first trench TR1 may extend in the first horizontal direction D1. In addition, the write structure WS may further include a barrier layer 44A disposed in the first trench TR1. The barrier layer 44A may be disposed conformally on the surface of the first trench TR1 and on the SOT patterns 42P, the electrically conductive layer 46A is disposed on the barrier layer 44A, and a part of the barrier layer 44A may be located between the electrically conductive layer 46A and each of the SOT patterns 42P accordingly. In some embodiments, a part of the barrier layer 44A may be sandwiched between one of the SOT patterns 42P and the dielectric layer (such as the dielectric layer composed of the dielectric layer 38 and the dielectric layer 40) in the second horizontal direction D2 orthogonal to the first horizontal direction D1 (such as the condition illustrated in FIG. 2) for improving the protection to the SOT patterns 42P. For example, the barrier layer 44A covering the SOT patterns 42P may be used to reduce negative influence caused by external substances passing through the dielectric layer (such as the dielectric layer 38 and/or the dielectric layer 40) and entering the SOT patterns 42P, but not limited thereto. In some embodiments, the write structure WS may include first portions P1 and second portions P2 alternately arranged in the first horizontal direction D1, each of the first portions P1 may consist of one of the SOT patterns 42P, the barrier layer 44A disposed above the SOT pattern 42P, and the electrically conductive layer 46A disposed above the SOT pattern 42P, and each of the second portions P2 may consist of a part of the barrier layer 44A located between the SOT patterns 42P in the first horizontal direction D1 and a part of the electrically conductive layer 46A located between the SOT patterns 42P in the first horizontal direction D1. In other words, the write structure WS may include the first portions P1, which consist of the SOT patterns 42P, the barrier layer 44A, and the electrically conductive layer 46A, and the second portions P2, which consist of the barrier layer 44A and the electrically conductive layer 46A, arranged alternately in the first horizontal direction D1 and connected with one another for reducing the overall electrical resistance of the write structure WS while maintaining the required programming performance and/or the required magnetization performance of the write structure WS.

In some embodiments, each of the MTJ structures MS may include a bottom electrode 24, a reference layer 26, a barrier layer 28, a free layer 30, and a spin-orbit torque layer (such as a SOT layer 32) stacked sequentially from bottom to top. Each of the SOT patterns 42P is connected with the SOT layer 32 of the MTJ structure MS disposed under the SOT pattern 42P, and the SOT layer 32 disposed above the free layer 30 and the corresponding SOT pattern 42P may include a SOT material, respectively. The SOT material may be defined as a material capable of generating the spin Hall effect and/or a material with greater spin-orbit coupling strength, so as to generate spin-orbit torque on the free layer 30 and change the direction of the magnetic torque of the free layer 30. The material composition of the SOT patterns may identical to or different from the material composition of the SOT layers 32 according to some design considerations. In some embodiments, the SOT layer 32 and other material layers in the MTJ structure MS may be formed concurrently by a patterning process, such as an ion beam etching (IBE) process or other suitable approaches for realizing the patterning effect, and at least a part of the SOT layer 32 may be used as a hard mask layer when other material layers are etched by the IBE process. Therefore, the hardness requirement for the SOT layer 32 is relatively high. Relatively, the SOT pattern 42P may not be patterned with other materials by a patterning process, such as a reactive-ion etching (RIE) process or other suitable approaches. Therefore, the hardness requirement for the SOT pattern 42P is relatively low, and a hardness of each of the SOT layers 32 may be greater than a hardness of each of the SOT patterns 42P accordingly. In addition, the electrical resistivity of the general SOT material is relatively high, the SOT layer 32 may be used to generate spin-orbit torque mainly when the SOT layer 32 exists in the semiconductor device, and the SOT pattern 42P that is relatively far from the free layer 30 may be formed with a SOT material having relatively low electrical resistivity for reducing the overall electrical resistance of the write structure WS. Therefore, the electrical resistivity of each of the SOT patterns 42P may be lower than the electrical resistivity of each of the SOT layers 32 under this situation. For example, the material of the SOT layer 32 may include hafnium (Hf), rhenium (Re), ruthenium (Ru), gold (Au), platinum (Pt), tantalum (Ta), tungsten (W), iridium (Ir), palladium (Pd), an alloy of the materials described above (such as IrPt, PtAu, PtPd, BiSb, and so forth), a compound of the materials described above (such as PrS, WTe₂, and so forth), or other suitable materials (such as BiSb), and the material of the SOT pattern 42P may include W, Au, Ti, Ta, BiSb, or other suitable materials. Additionally, in some embodiments, when the semiconductor device 100 is viewed in the vertical direction D3, the SOT pattern 42P may completely cover and/or overlap the corresponding MTJ structure MS and the SOT layer 32 in the corresponding MTJ structure MS. In other words, a length of each of the SOT patterns 42P in the first horizontal direction D1 and a length of each of the SOT patterns 42P in the second horizontal direction D2 may be greater than a length of each of the SOT layers 32 in the first horizontal direction D1 and a length of each of the SOT layers 32 in the second horizontal direction D2, respectively, and a projection are of each of the SOT patterns 42P in the vertical direction D3 may be greater than a projection area of each of the SOT layers 32 in the vertical direction D3.

In some embodiments, the SOT pattern 42P may directly contact the corresponding SOT layer 32, but not limited thereto. The free layer 30 and the reference layer 26 may include ferromagnetic materials, such as iron, cobalt, nickel, cobalt-iron (CoFe), cobalt-iron-boron (CoFeB), or other suitable ferromagnetic materials. In some embodiments, the reference layer 26 and an antiferromagnetic layer (not illustrated) may constitute a pinned layer with fixed direction of magnetic torque. The antiferromagnetic layer may include antiferromagnetic materials, such as iron manganese (FeMn), platinum manganese (PtMn), iridium manganese (IrMn), nickel oxide (NiO), a cobalt/platinum (Co/Pt) multilayer, or other suitable antiferromagnetic materials. The barrier layer 28 may include insulation materials, such as magnesium oxide (MgO), aluminum oxide, or other suitable insulation materials, and the bottom electrode 24 may include metallic materials, such as tantalum (Ta), platinum (Pt), ruthenium (Ru), a stacked layer of the above-mentioned materials, an alloy of the above-mentioned materials, or other suitable conductive materials. In addition, the dielectric layer 12, the dielectric layer 14, the dielectric layer 20, the dielectric layer 36, and the dielectric layer 38 described above may respectively include an oxide dielectric material, a low dielectric constant dielectric material (such as a dielectric material with dielectric constant lower than 2.9, but not limited thereto), or other suitable dielectric materials, and the dielectric layer 40 and the dielectric layer 50 may respectively include a low dielectric constant dielectric material or an ultra low dielectric constant (ULK) dielectric material (such as a dielectric material with dielectric constant lower than 2.7, but not limited thereto), such as benzocyclclobutene (BCB), hydrogen silsesquioxane (HSQ), methyl silesquioxane (MSQ), hydrogenated silicon oxycarbide (SiOC—H), a porous dielectric material, or other suitable dielectric materials. In addition, the hardness of a low dielectric constant dielectric material (such as a porous structure applied to lower the dielectric constant) is relatively lower normally. Therefore, for avoiding influencing the related manufacturing yield, a material having a relatively high dielectric constant and a relatively high hardness is used to form the dielectric layer 38 preferably, and a material having relatively low dielectric constant may be used to formed the dielectric layer 40 for reducing signal interference between the write structures WS adjacent to each other and/or between the interconnection structures CS adjacent to each other. Therefore, the dielectric constant of the dielectric layer 40 may be lower than the dielectric constant of the dielectric layer 38, but not limited thereto. The stop layer 18 and the stop layer 48 may include nitrogen doped carbide (NDC), silicon nitride, silicon carbon nitride (SiCN), or other suitable insulation materials, and the capping layer 34 may include silicon nitride or other dielectric materials different from the dielectric layer 36 for being used as an etching stop layer, but not limited thereto.

In some embodiments, the connection structure 16, the interconnection structure CS, the connection structure CT, the first electrode E1, and the second electrode E2 may respectively include a barrier layer and tan electrically conductive layer disposed on the barrier layer. The barrier layer may include titanium, titanium nitride, tantalum, tantalum nitride, or other suitable electrically conductive barrier materials, and the electrically conductive layer may include tungsten, copper, aluminum, titanium aluminide, cobalt tungsten phosphide, or other suitable electrically conductive materials with relatively low electrical resistivity. For example, the connection structure 22 may include a barrier layer 22A and an electrically conductive layer 22B disposed on the barrier layer 22, and the interconnection structure CS may include a barrier layer 44B and an electrically conductive layer 46B disposed on the barrier layer 44B, but not limited thereto. In some embodiments, the barrier layer 44A and the electrically conductive layer 46A in the write structure WS and the barrier layer 44A and the electrically conductive layer 46A in the interconnection structure CS may be formed concurrently by the same process, the material composition of the barrier layer 44A may be identical to the material composition of the barrier layer 44B, and the material composition of the electrically conductive layer 46A may be identical to the material composition of the electrically conductive layer 46B, but not limited thereto.

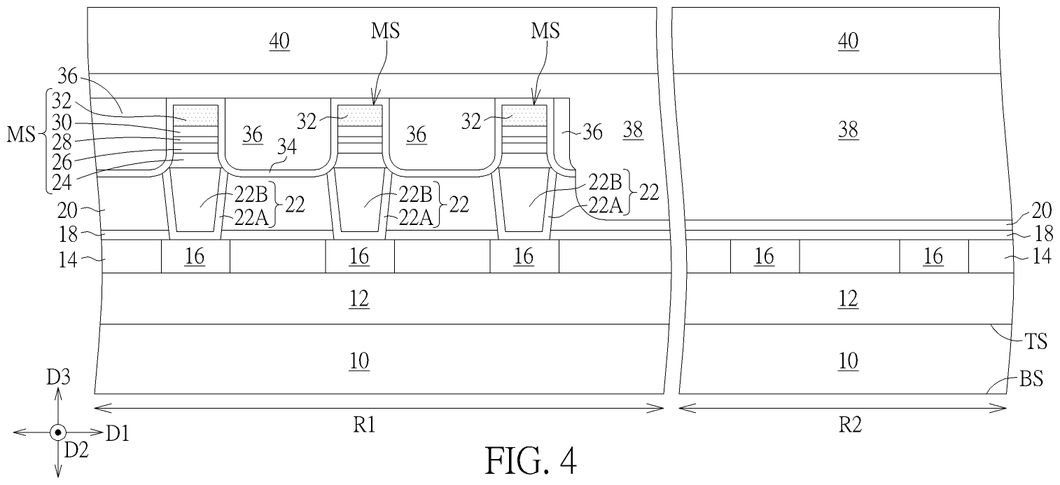

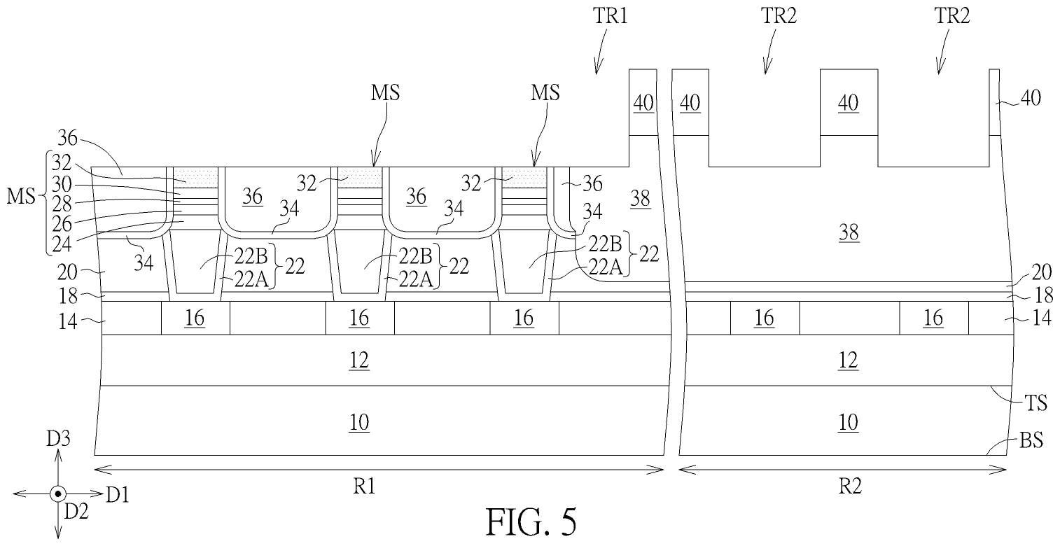

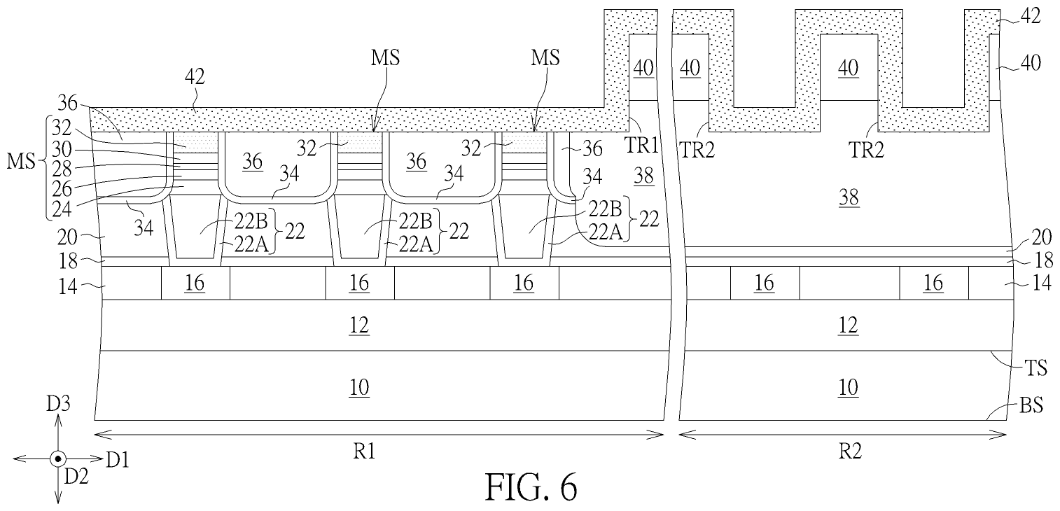

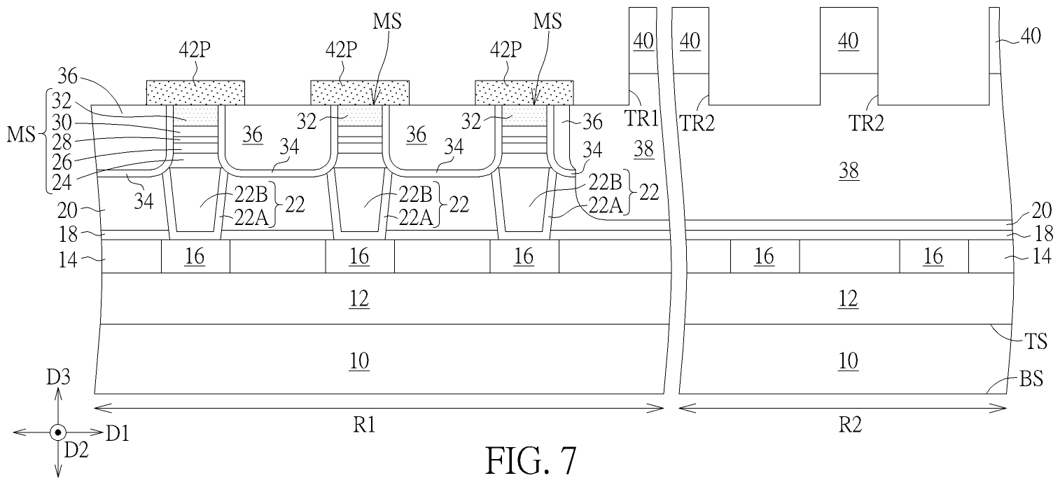

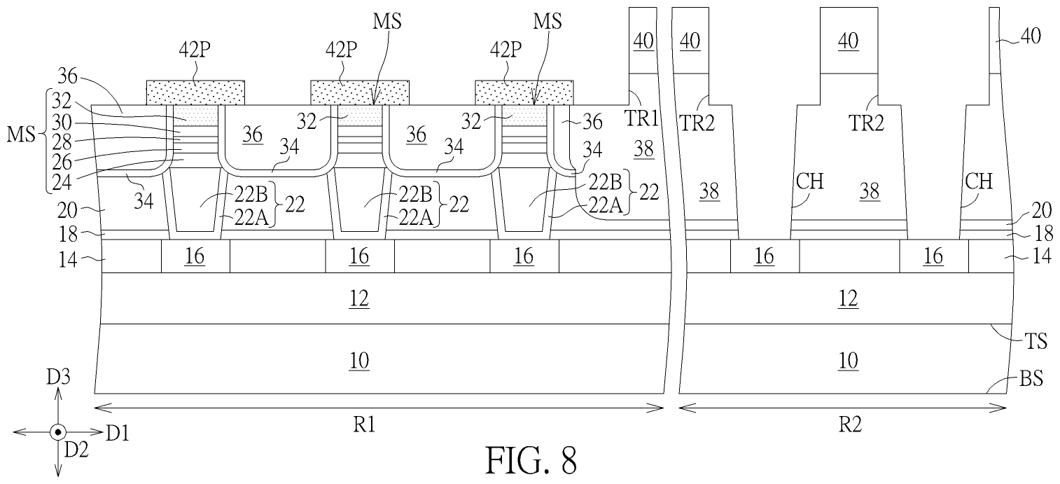

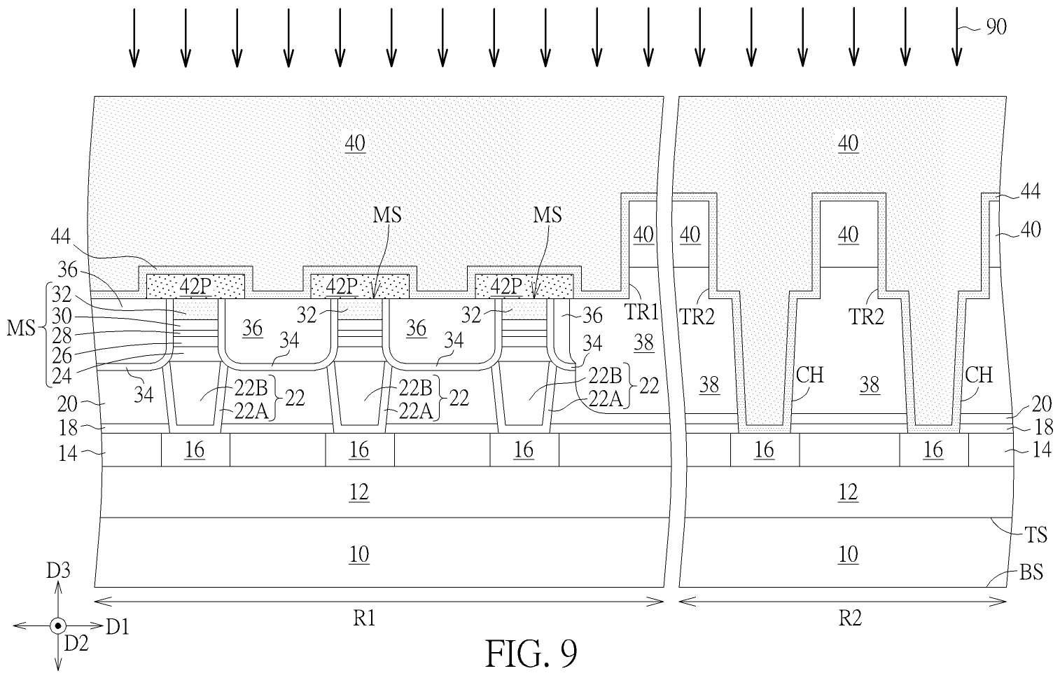

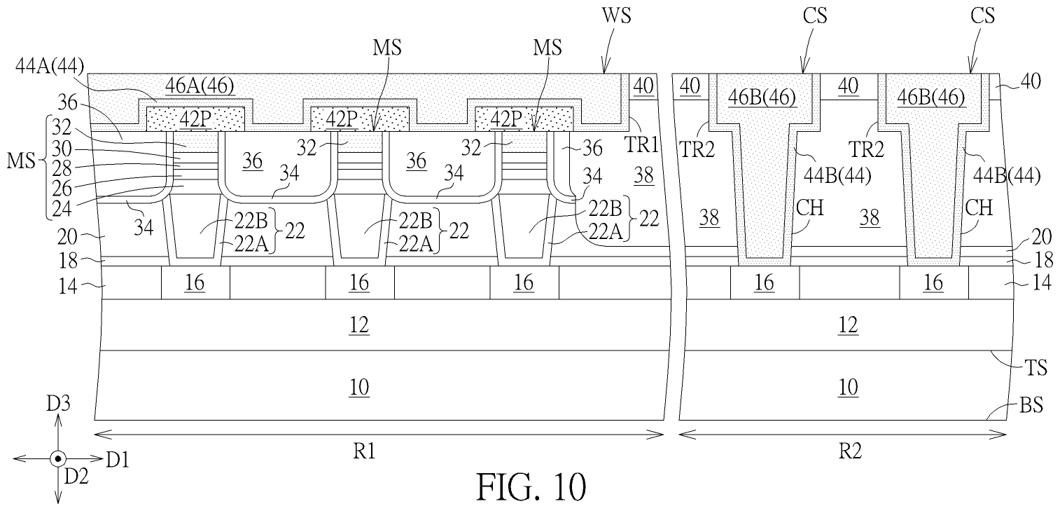

Please refer to FIGS. 1-10. FIGS. 4-10 are schematic drawings illustrating a manufacturing method of a semiconductor device according to an embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, and FIG. 10 is a schematic drawing in a step subsequent to FIG. 9. In some embodiments, FIG. 1 may be regarded as a schematic drawing in a step subsequent to FIG. 10, but not limited thereto. As shown in FIG. 1, a manufacturing method of a semiconductor device is provided in this embodiment and includes the following steps. The MTJ structures MS are formed above the substrate 10. The write structure WS is formed on the MTJ structures MS, the write structure WS is connected with the MTJ structures MS, and the write structure WS includes the SOT patterns 42P and the electrically conductive layer 46A. The SOT patterns 42P are separated from one another, and each of the SOT patterns is disposed on and connected with one of the MTJ structures MS. The electrically conductive layer 46A covers the SOT patterns 46A, and the electrically conductive layer 46A is partly disposed above the SOT patterns 42P in the vertical direction D3 and partly disposed between the SOT patterns 42P in the first horizontal direction D1.

Specifically, the manufacturing method in this embodiment may include but is not limited to the following steps. As shown in FIG. 4, the dielectric layer 12, the dielectric layer 14, the connection structure 16, the stop layer 18, and the dielectric layer 20 may be formed on the first region R1 and the second region R2 of the substrate 10. Subsequently, the connection structures 22, the MTJ structures MS, the capping layer 34, and the dielectric layer 36 may be formed above the first region R1. The dielectric layer 38 and the dielectric layer 40 may then be formed above the first region R1 and the second region R2. In some embodiments, the dielectric layer 38 may be formed by spin coating, and the dielectric layer 38 may have a relatively flat top surface accordingly, but not limited thereto. The dielectric layer 38 and the dielectric layer 40 may be regarded as a first layer and a second layer in a dielectric layer, respectively, and the dielectric layer may cover the MTJ structures MS. Subsequently, as shown in FIG. 5, the first trench TR1 may be formed in the dielectric layer (such as the dielectric layer composed of the dielectric layer 38 and the dielectric layer 40) located above the first region R1, and the second trench TR2 may be formed in the dielectric layer (such as the dielectric layer composed of the dielectric layer 38 and the dielectric layer 40) located above the second region R2. The first trench TR1 may be formed by removing a part of the dielectric layer 40, a part of the dielectric layer 38, a part of the capping layer 34, and a part of the dielectric layer 36, and the first trench TR1 may expose the corresponding MTJ structures MS (such as the SOT layers 32 in the MTJ structures MS). In some embodiments, the first trench TR1 and the second trench TR2 may be formed concurrently by the same process (such as a photolithographic and etching process, but not limited thereto), and the depth of the first trench TR1 may be substantially equal to the depth of the second trench TR2, but not limited thereto.

As shown in FIG. 6 and FIG. 7, the SOT patterns 42P may be formed in the first trench TR1, and the SOT patterns 42P are separated from one another. In some embodiments, a SOT material 42 may be formed on surfaces of the first trench TR1, the second trench TR2, and the dielectric layer 40, and a patterning process may be performed to the SOT material 42 for forming the SOT patterns 42P. The SOT material 42 formed in the second trench TR2 and the SOT material 42 formed on the dielectric layer 40 may be completely removed by the patterning process accordingly. As shown in FIG. 8, the contact hole CH may be formed under the second trench TR2, the contact hole CH is connected with the second trench TR2, and the SOT patterns 42P are formed in the first trench TR2 before the contact hole CH is formed for avoiding the SOT material 42 remaining in the deeper contact hole CH without being removed completely, but not limited thereto. The contact hole CH may penetrate through a part of the dielectric layer 38, the dielectric layer 20, and the stop layer 18 for exposing the corresponding connection structure 16. As shown in FIG. 9, a barrier material 44 and an electrically conductive material 46 may be globally formed on the substrate 10, and the electrically conductive material 46 may be formed on the barrier material 44. The barrier material 44 may be formed conformally on the surface of the first trench TR1, the SOT patterns 42P, the surface of the second trench TR2, the surface of the contact hole CH, and the surface of the dielectric layer 40, and the electrically conductive material 46 may be partly formed in the first trench TR1, partly formed in the second trench TR2, and partly formed in the contact hole CH. In some embodiments, the second trench TR2 and the contact hole CH may be fully filled with the barrier material 44 and the electrically conductive material 46; the first trench TR1 may be fully filled with the barrier material 44, the electrically conductive material 46, and the SOT patterns 42P; and the barrier material 44 and the electrically conductive material 46 may be partially formed outside the first trench TR1, the second trench TR2, and the contact hole CH.

Subsequently, as shown in FIG. 9 and FIG. 10, a planarization process 90 may be performed for removing the barrier material 44 and the electrically conductive material 46 located outside the first trench TR1, the second trench TR2, and the contact hole CH, so as to form the electrically conductive layer 46A and the barrier layer 44A in the first trench TR1 and to form the electrically conductive layer 46B and the barrier layer 44B in the second trench TR2 and the contact hole CH. Accordingly, the write structure WS and the interconnection structure CS may be formed above the first region R1 and the second region R2, respectively. By the manufacturing method described above, the electrically conductive layer 46A and the barrier layer 44A of the write structure WS and the interconnection structure CS may be formed concurrently by the same process, but not limited thereto. In the write structure WS, the barrier layer 44A may be formed in the first trench TR1, the barrier layer 44A may be formed on the SOT patterns 42P and the surface of the first trench TR1, and the electrically conductive layer 46A may be formed on the barrier layer 44A. In the interconnection structure CS, the electrically conductive layer 46B and the barrier layer 44B may be partly formed in the contact hole CH and partly formed in the second trench TR2. In some embodiments, the planarization process 90 may include a chemical mechanical polishing (CMP) process, an etching back process, or other suitable planarization approaches. A part of the dielectric layer 40 may be removed by the planarization process 90, and the top surface of the write structure WS, the top surface of the interconnection structure CS, and the top surface of the dielectric layer 40 may be substantially coplanar, but not limited thereto. It is worth noting that the method of forming the write structure WS and the interconnection structure CS in this invention may include but is not limited to the steps illustrated in FIGS. 5-10 described above, and the write structure WS and the interconnection structure CS illustrated in FIG. 10 may be formed by other suitable approaches according to some design considerations. Subsequently, as shown in FIG. 10 and FIG. 1, the stop layer 48, the dielectric layer 50, the first electrode E1, the second electrode E2, and the connection structures CT described above may be formed for forming the semiconductor device 100 illustrated in FIG. 1.

To summarize the above descriptions, in the semiconductor device and the manufacturing method thereof according to the present invention, the SOT patterns and the electrically conductive layer are disposed in the write structure, and the electrically conductive layer with relatively low electrical resistivity may be used to reduce the overall electrical resistance of the write structure while maintaining the required programming performance and/or the required magnetization performance. The operation performance of the memory cell and the semiconductor device may be enhanced and/or the power consumption for operating the semiconductor device may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
magnetic tunnel junction (MTJ) structures disposed above the substrate; and
a write structure disposed on and connected with the magnetic tunnel junction structures, wherein the write structure comprises:
spin-orbit torque (SOT) patterns separated from one another, wherein each of the spin-orbit torque patterns is disposed on and connected with one of the magnetic tunnel junction structures; and
an electrically conductive layer covering the spin-orbit torque patterns, wherein the electrically conductive layer is partly disposed above the spin-orbit torque patterns in a vertical direction and partly disposed between the spin-orbit torque patterns in a first horizontal direction.

2. The semiconductor device according to claim 1, wherein each of the magnetic tunnel junction structures comprises:
a free layer; and
a spin-orbit torque layer disposed above the free layer, wherein each of the spin-orbit torque patterns is connected with the spin-orbit torque layer of the magnetic tunnel junction structure disposed under the spin-orbit torque pattern.

3. The semiconductor device according to claim 2, wherein a material composition of the spin-orbit torque patterns is different from a material composition of the spin-orbit torque layers.

4. The semiconductor device according to claim 2, wherein a hardness of each of the spin-orbit torque layers is greater than a hardness of each of the spin-orbit torque patterns.

5. The semiconductor device according to claim 2, wherein electrical resistivity of each of the spin-orbit torque patterns is lower than electrical resistivity of each of the spin-orbit torque layers.

6. The semiconductor device according to claim 1, further comprising:
a dielectric layer disposed above the substrate, wherein the write structure is disposed in the dielectric layer and elongated in the first horizontal direction, and the magnetic tunnel junction structures are arranged in the first horizontal direction.

7. The semiconductor device according to claim 6, wherein the write structure further comprises:
a barrier layer disposed between the electrically conductive layer and each of the spin-orbit torque patterns, wherein a part of the barrier layer is sandwiched between one of the spin-orbit torque patterns and the dielectric layer in a second horizontal direction orthogonal to the first horizontal direction.

8. The semiconductor device according to claim 7, wherein the write structure comprises first portions and second portions alternately arranged in the first horizontal direction, each of the first portions consists of one of the spin-orbit torque patterns, the barrier layer disposed above the spin-orbit torque pattern, and the electrically conductive layer disposed above the spin-orbit torque pattern, and each of the second portions consists of a part of the barrier layer located between the spin-orbit torque patterns in the first horizontal direction and a part of the electrically conductive layer located between the spin-orbit torque patterns in the first horizontal direction.

9. The semiconductor device according to claim 6, wherein the dielectric layer comprises:
a first layer; and
a second layer disposed on the first layer, wherein the write structure is partly disposed in the first layer and partly disposed in the second layer, and a dielectric constant of the second layer is lower than a dielectric constant of the first layer.

10. The semiconductor device according to claim 1, further comprises:
a first electrode and a second electrode, wherein the first electrode and the second electrode are disposed on and connected with the write structure, and the first electrode and the second electrode are located above two opposite ends of the write structure in the first horizontal direction, respectively.

11. A manufacturing method of a semiconductor device, comprising:
forming magnetic tunnel junction (MTJ) structures above a substrate; and
forming a write structure on the magnetic tunnel junction structures, wherein the write structure is connected with the magnetic tunnel junction structures, and the write structure comprises:
spin-orbit torque (SOT) patterns separated from one another, wherein each of the spin-orbit torque patterns is disposed on and connected with one of the magnetic tunnel junction structures; and
an electrically conductive layer covering the spin-orbit torque patterns, wherein the electrically conductive layer is partly disposed above the spin-orbit torque patterns in a vertical direction and partly disposed between the spin-orbit torque patterns in a first horizontal direction.

12. The manufacturing method of the semiconductor device according to claim 11, wherein a method of forming the write structure comprises:
forming a dielectric layer on the substrate, wherein the dielectric layer covers the magnetic tunnel junction structures;
forming a first trench in the dielectric layer, wherein the first trench exposes each of the magnetic tunnel junction structures;
forming the spin-orbit torque patterns in the first trench; and
forming the electrically conductive layer in the first trench.

13. The manufacturing method of the semiconductor device according to claim 12, wherein the substrate comprises a first region and a second region, the magnetic tunnel junction structures and the write structure are disposed above the first region, and the manufacturing method further comprises:
forming an interconnection structure above the second region, wherein the electrically conductive layer of the write structure and the interconnection structure are formed concurrently by the same process.

14. The manufacturing method of the semiconductor device according to claim 13, wherein the dielectric layer is formed above the first region and the second region, and a method of forming the interconnection structure comprises:
forming a second trench in the dielectric layer located above the second region, wherein the first trench and the second trench are formed concurrently by the same process;
forming a contact hole under the second trench, wherein the contact hole is connected with the second trench, and the spin-orbit torque patterns are formed in the first trench before the contact hole is formed;
forming an electrically conductive material above the substrate, wherein the electrically conductive material is partly formed in the first trench, partly formed in the second trench and the contact hole, and partly formed outside the first trench, the second trench, and the contact hole; and
performing a planarization process for removing the electrically conductive material located outside the first trench, the second trench, and the contact hole.

15. The manufacturing method of the semiconductor device according to claim 12, wherein the dielectric layer comprises:
a first layer; and
a second layer disposed on the first layer, wherein the write structure is partly disposed in the first layer and partly disposed in the second layer, and a dielectric constant of the second layer is lower than a dielectric constant of the first layer.

16. The manufacturing method of the semiconductor device according to claim 12, wherein the first trench is elongated in the first horizontal direction, the magnetic tunnel junction structures are arranged in the first horizontal direction, and the method of forming the write structure further comprises:
forming a barrier layer in the first trench, wherein the barrier layer is formed on a surface of the first trench and the spin-orbit torque patterns, the electrically conductive layer is formed on the barrier layer, and a part of the barrier layer is sandwiched between one of the spin-orbit torque patterns and the dielectric layer in a second horizontal direction orthogonal to the first horizontal direction.

17. The manufacturing method of the semiconductor device according to claim 11, wherein each of the magnetic tunnel junction structures comprises:
a free layer; and
a spin-orbit torque layer disposed above the free layer, wherein each of the spin-orbit torque patterns is connected with the spin-orbit torque layer of the magnetic tunnel junction structure disposed under spin-orbit torque pattern.

18. The manufacturing method of the semiconductor device according to claim 17, wherein a material composition of the spin-orbit torque patterns is different from a material composition of the spin-orbit torque layers.

19. The manufacturing method of the semiconductor device according to claim 17, wherein a hardness of each of the spin-orbit torque layers is greater than a hardness of each of the spin-orbit torque patterns.

20. The manufacturing method of the semiconductor device according to claim 17, wherein electrical resistivity of each of the spin-orbit torque patterns is lower than electrical resistivity of each of the spin-orbit torque layers.
